(19) United States
(12) Patent Application Publication
(10) Pub. No.: US 2005/0245062 A1
(43) Pub. Date: Nov. 3, 2005

(54) Single row bond pad arrangement

(76) Inventors: Jeff Kingsbury, Arundel, ME (US); Stephen A. Martin, South Portland, ME (US)

Correspondence Address: CESARI AND MCKENNA, LLP, 88 BLACK FALCON AVENUE, BOSTON, MA, 02210, US

(21) Appl. No.: 10/835,212

(22) Filed: Apr. 29, 2004

(51) Int. Cl. H01L 21/44

(52) U.S. Cl. 438/617

(57) ABSTRACT

An integrated circuit chip with its interconnecting pads re-arranged in substantially a straight line. The pads are ordered in the straight line so that wire bond connections to contact terminal of an IC package allows the wire bonds to not interfere with each other by traveling under or over other wire bonds. This re-arrangement and ordering of an IC's pads allows a single die constructed in accordance with this invention to be mounted in both a package that is designed to accept a die-down type chip and a package designed to accept a die-up type chip. This mounting of the single chip occurs directly without any other transition artifacts, like transition substrates, etc., that would carry the reversal of the effective pad locations.

### RELATED APPLICATIONS

The present application is related to the pending U.S. patent application Ser. No. 09/823,600, entitled “Packaging System for Die-Up Connection for a Die-Down die Oriented Integrated Circuit,” filed Mar. 30, 2001, and of common ownership with the present application.

### BACKGROUND OF THE INVENTION

1. Field of the Invention

The present invention relates to integrated circuit (IC) packaging. More particularly, the present invention relates to arranging a die that can be directly packaged into a die-down or a die-up type package that requires no other auxiliary transition substrates or boards.

2. Description of the Prior Art

Integrated circuit (IC) packages are ubiquitous in electronics and have been so for many years. Typically retail consumers are familiar with IC as small packages mounted onto a printed circuit (PC) board in their home computers, television sets, cell phones, etc. The actual packages often are dual-in-line (DIP) or the low profile surface mounts that come in a variety of types, gull wing, J-leaded, ball grids, etc. Herein, “IC” will refer to the semiconductor chip itself and “IC package” or “package” will refer to the plastic or ceramic housing for the IC. Also, IC, “die” and “chip” are synonymous herein.

In this application the connections between the IC and the IC package are made by wire bonds with materials and using techniques that are well known in the art. Typically the IC is bonded to a support substrate or structure within the package and the wires bonds are electrically connected between pads (designed to accept such wire leads) on the IC and electrical contact terminals in the package that are routed through the package for soldering or otherwise connecting to conductive runs on the PC board.

However, there are two mutually exclusive IC or die types that are found in the art. One type, called a die-down type, is mounted in a package with the die pads facing the PC board to which the package is mounted. The second type, called a die-up type, is mounted in a different package with the pads facing up away from the PC board. Herein, die-up may be referred to as die pads up, and die-down may be referred to as die pads down.

The examples herein illustrate IC's with six pins or pads. But, the present invention applies to IC's having any number of pads.

FIG. 1A Shows an example of a prior art die 12 that has six bond pads located about the periphery. Each bond pad 18 has an assigned geographic position that for logistical circuit design purposes is numbered in counter-clock-wise order about the periphery with a first pad “pin 1” 13 that has a unique geometry to make it optically distinguishable. The remaining pads are assigned location numbers in a counter-clock-wise fashion (looking at the pads) regardless of the die intended orientation. In all the cases referenced in FIGS. 3 to 12, there are 6 pads, which are numbered 1-6 respectively, to hold consistent the idea of changing die layout. The die in FIG. 1A has a net list 19 shown in FIG. 1C and also referenced herein as “Table 1.” The net list 19 establishes the relationship between the geographic location of each die pad 18 and the electrical functions 22 of the circuitry of the die 12 connected to those pads 18. The combination of the die pads 18 and die functions 22 make a given die suitable for use in a variety of packages that may be large or small. In the case of FIG. 1A this die 12 is configured for pads down orientation in the package relative to the package defined bottom.

FIG. 1B is a bottom through view of die 12. This establishes the direction of viewing a die from the back side because it is flipped over relative to the viewing direction. Since the die pads are numbered 1 through 6 in a counter-clock-wise fashion the flip could occur on any axis. For the purpose of illustrating clearly in this document all flips of the die have been performed laterally about the vertical axis A-A′ or an equivalent vertical axis for any other chip with vertially arranged pads. Like flipping over a clock laterally about an axis line drawn from 6 o'clock to 12 o'clock all positions appear transposed like wise. The clock position 1 moves to 11, 2 moves to 10, and so on and so forth. In the die examples of this document the bond pad geographical position 1 moves to 6, then 2 moves to 5, and finally 3 moves to 4 when you physically flip the die about the vertical axis and view it as bottom through view.

The table 1 is the net list 19 FIGS. 1A and 1B. This is a configuration of the electrical signals at the each pad 18 for the pads down orientation in the package relative to the defined package bottom.

FIG. 2A shows an example of a prior art die 16 that has six bond pads located about the periphery. Each bond pad 17 has an assigned geographic position that for logistical circuit design purposes is numbered in counter clock-wise-order about the periphery with a first “pin 1” 21 that has a unique geometry to make it optically distinguishable. The remaining pads are labeled in a counter-clock-wise fashion regardless of the die intended orientation. In all the cases referenced below in FIGS. 3 to 12 there are 6 pads with item numbers 1-6 respectively. The die in FIG. 2A has a net list 21, shown in FIG. 2C and also referenced as “Table 2.” The net list 20 establishes the relationship between the geographic location of each die pad 17 and the electrical functions 22 of the circuitry of the die 14 connected to each pad 18. The combination of each die pad 18 with the die functions 22 make a given die suitable for use in a variety of packages that may be large or small. In the case of FIG. 2A this die 14 is configured for pads up orientation in the package relative to the package defined bottom.

FIG. 2B is a bottom through view of die 14. This establishes the perspectives of viewing a die from the back side because it is flipped laterally as defined above for FIG. 1A. Since the die pads are numbered 1 through 6 in a counter-clock-wise fashion the flip could occur on any axis. For the purpose of illustrating clearly in this document, all flips of the die have been performed laterally about the axis B-B.′

Table 2 is the net list 22 for FIGS. 2A and 2B. This is a configuration of the electrical signals at each pad 18 for the pads up orientation in the package relative to the defined package bottom.

FIG. 3A shows an end view of the die-down type IC 12 mounted in a package with the surrounding external plastic mold 38, viewed transparently here, showing the die 12 attached to a die attach paddle (DAP) 28 of a leadframe. The IC 12 is attached by an adhesive material 10 (known in the art) to the bottom side of the die attach paddle 28 with each die pad 18 facing the printed circuit (PC) board 42. One wire bond 24 per die pad 18 is used to electrically connect to each terminal 26 that extend externally out of the package to make electrical contact by solder 9 with the copper land pattern 44 on the PC board 42. Surface 34 identifies what is referenced as the package top and surface 36 identifies what is referenced as the package bottom that faces the PC board 42.

FIG. 3B shows a die down configured die. The die 12 with the signal names 19 and the first pad “pin 1” 13 to establish orientation of the die-down configured die 12 as it is mounted on the package die attach paddle 28.

FIG. 3C is a bottom up view of the package (transparent) surface 36 in FIG. 3A showing the die 12 pads FIG. The electrical connectivity of the die 12 pads 18 to the leads 26 of the package is done with wire bonds 24. Each wire bond 24 connects one die pad 18 to one lead 26. The connection instruction used to arrive at this assembly is the net list 19 Table 1.

FIG. 3D is an isometric view of FIG. 3A. The mold compound 38 has been removed from the FIG. to clearly view the package interior. The package assembly from FIG. 3C is arranged into position onto the PC board to establish the proper net list connection from the PC board 42 to the package contacts 26.

Note, it is the responsibility of the IC manufacturer to make the final packaged device net list match the required predetermined PCB function locations. Therefore, if a secondary package could be made to fit the land pattern but the assembly requires the die to be in the pads up orientation the die needs to be configured to avoid crossing wire issues. The below prior art represents one of those configurations that would result in crossing wire issues and not solve the problem of having a die that can be mounted in a die-up package or die-down package. Hence, the die in FIGS. 5 and 6 represent redesigned dies that come from FIG. 2 and are assembled into die-up configured packages.

FIG. 4A shows an end view of a die-up type IC 14 mounted in a package with the external plastic 38, viewed transparently here, showing the die 14 attached to a substrate 32. The IC 14 is attached by an adhesive material 10 to the substrate 32 with each die pad 18 facing up and away from the PC board 42. One wire bond 24 per die pad 18 is used to electrically connect to each substrate terminal 46. Each substrate terminal 46 is connected from the top of the substrate 30 to the bottom external leads 40 to make electrical contact by solder 9 with the copper land pattern 44 on the PC board 42. Surface 34 identifies what is referenced as the package top and surface 36 identifies what is referenced as the package bottom that faces the PC Board 42.

FIG. 4B shows a die-up configured die. The die 14 with the signal names 22 and the first pad “pin 1” 21 to establish orientation of the die-up configured die 14 as it is mounted on the die-up configured package substrate 32.

FIG. 4C shows a top down view of the package relative to the surface 34 in FIG. 4A with the die 14 from FIG. 4B overlaid into position without flipping onto the substrate. The package plastic mold 38 is considered transparent to view the interior of the package. The electrical connectivity of the die 14 to the substrate terminals 46 is done with wire bonds. Each wire bond 24 connects one die pad 18 to one substrate terminal 46. The connection instruction used to arrive at this assembly is net list 20 Table 2.

FIG. 4D is an isometric view of FIG. 4A. The mold compound 38 has been removed from the FIGS. to clearly view the package interior. The package assembly from FIG. 4C is overlaid into position with out rotation to establish the proper net list connection from the PC board 42 to the package FIG. 4C.

FIG. 5A shows an end view of a die-up type IC 14 mounted in a package with the external plastic 38, viewed transparently here, showing the die 14 attached to a die attach paddle (DAP) 30 of the leadframe. The IC 14 is attached by an adhesive material 10 to the top side of the die attach paddle 30 with each die pad 18 facing up and away from the PC board 42. One wire bond 24 per die pad 18 is used to electrically connect to each terminal lead 26 that extend externally out of the package to make electrical contact by solder 9 with the copper land pattern 44 on the PC board 42. Surface 34 identifies what is referenced as the package top and surface 36 identifies what is referenced as the package bottom that faces the PC Board 42.

FIG. 5B shows a die-up configured die. The die 14 with the signal names 22 and the first pad “pin 1” 21 to establish orientation of the die-up configured die 14 as it is mounted on the die-up package die attach paddle 30.

FIG. 5C shows a top down view of the package relative to the surface 34 in FIG. 5A with the die 14 from FIG. 5B overlaid into position without flipping. The package plastic mold 38 is transparent to view the interior of the package. The electrical connectivity of the die 14 to the leads of the package 26 is done with wire bonds 24. Each wire bond 24 connects one die pad 18 to one lead 26. The connection instruction used to arrive at this assembly is net list 20 Table 2.

FIG. 5D is an isometric view of FIG. 5A. The plastic mold compound 38 has been removed from the FIG. to clearly view the package interior. The package assembly from FIG. 5C is overlaid into position with out flipping to establish the proper net list connection from the PC board 42 to the package of FIG. 5C.

FIG. 6A shows an end view example of a die 14 configured for a die pads up lead frame, mounted in a die-down package. This end view of the package shows the die 14 mounted in a package with the external plastic 38, viewed transparently here, showing the die 14 attached to a die attach paddle 28 of the leadframe. The IC 14 is attached by an adhesive material 10 to the bottom side of the die attach paddle 28 with each die pad 18 facing down toward the PC board 42, note opposite of the intended application of the die-up configured die 14. One wire bond 24 per die pad 18 is used to electrically connect to each terminal 26 that extend externally out of the package to make electrical contact by solder 9 with the copper land pattern 44 on the PC board 42. Surface 34 identifies what is referenced as the package top and surface 36 identifies what is referenced as the package bottom that faces the PC board 42.

FIG. 6B shows a die-up configured die. The die 14 with the signal names 22 and the first pad “pin 1” 21 to establish orientation of the die-up configured die 14 as it could be mounted on the die-down configured package die attach paddle 28.

FIG. 6C shows a bottom up view of the package relative to the surface 36 in FIG. 6A with the die 14 from FIG. 6B overlaid into position without rotation onto the DAP. The package plastic mold 38 is transparent to view the interior of the package. The electrical connectivity of the die 14 to the leads of the package 26 is done with wire bonds. Each wire bond 24 connects one die pad 18 to one lead 26. The connection instruction used to arrive at this assembly is net list 20 of Table 2. This assembly FIG. 6C illustrates why a die-up configured die can not be placed in a die-down package, because the wire bond cross each other and this is not a reliable technique and it is not used in practice. The crossing points will create conductive paths that will make the die inoperable. Hence, “POWER” shorts to “GROUND”, “CONTROL 1” shorts to “CONTROL 2”, and “DATA IN” shorts to “DATA OUT” in the example. This is why, in the past, two different die designs were needed for die-up and die-down packages.

FIG. 6D is an isometric view of FIG. 6A. The mold compound 38 has been removed from the FIG. to clearly view the package interior. The package assembly from FIG. 6C is arranged and then overlaid into position to establish the proper net list connection from the PCB 42 to the package FIG. 6C. This illustration shows more perspective on the crossing shorting wires that result from using a die-up configured die in a die-down package.

FIG. 7A shows an end view example of a die 12 configured for a die pads down lead frame in a die pads up package. This end view of the package shows the die 12 mounted in a package with the external plastic 38, viewed transparently here, showing the die 12 attached to a substrate 32. The IC is attached by an adhesive material 10 to the substrate 32 with each die pad 18 facing up and away from the PC board 42. One wire bond 24 per die pad 18 is used to electrically connect to each substrate terminal 46. Each substrate terminal 46 is connected from the top of the substrate 30 to the bottom external leads 40 to make electrical contact by solder 9 with the copper land pattern 44 on the PC board 42. Surface 34 identifies what is referenced as the package top and surface 36 identifies what is referenced as the package bottom that faces the PC board 42.

FIG. 7B shows die-down configured die. The die 12 with the signal names 22 and the first pad “pin 1” 13 to establish orientation of the die-down configured die 12 as it is mounted on the die-up configured package substrate 32.

FIG. 7C shows a top down view of the package relative to the surface 34 in FIG. 7A with the die 12 from FIG. 1A overlaid into position onto the substrate 32. The package plastic mold 38 is transparent to view the interior of the package. The electrical connectivity of the die 12 to the substrate terminals 46 is done with wire bonds each wire bond 24 connects one die pad 18 to one substrate terminal 46. The connection instruction used to arrive at this assembly is net list 19 Table 1.

FIG. 7D is an isometric view of FIG. 7A. The mold compound 38 has been removed from the FIG. to clearly view the package interior. The package assembly from FIG. 7C is overlaid into position to establish the proper net list connection from the PCB 42 to the package FIG. 7C. This illustrates the crossing and shorting wires that result from using a die-down configured die in a die-up package.

The assembly of FIGS. 7A-7D demonstrates why a die-down configured die can not be placed in a die-up package. The wire bonds 24 cross each other and may create conductive paths that will make the die inoperable. Hence, “POWER” shorts to “GROUND”, “CONTROL 1” shorts to “CONTROL 2”, and “DATA IN” shorts to “DATA OUT” in the example. This is why in the past, two different die designs have been needed for die-up and die-down packages.

FIG. 8A shows an end view example of a die 12 configured for a die pads down lead frame in a die pads up package. This end view of the package shows the die 12 mounted in a package with the external plastic 38, viewed transparently here, showing the die 12 attached to a die attach paddle 30 of the leadframe. The IC 12 is attached by an adhesive material 10 to the die attach paddle 30 with each die pad 18 facing up and away from the PC board 42. One wire bond 24 per die pad 18 is used to electrically connect to each terminal lead 26 that extend externally out of the package to make electrical contact by solder 9 with the copper land pattern 44 on the PC board 42. Surface 34 identifies what is referenced as the package top and surface 36 identifies what is referenced as the package bottom that faces the PC Board 42.

FIG. 8B shows die down configured die 12. The die 12 with the signal names 22 and the first pad “pin 1” 13 to establish orientation of the die-down configured die 12 as it is mounted on the die up package die attach paddle 30.

FIG. 8C shows a top down view of the package relative to the surface 34 in FIG. 8A with the die 12 from FIG. 8B overlaid into position without rotation. The package plastic mold 38 is transparent to view the interior of the package. The electrical connectivity of the die 12 to the leads of the package 26 is done with wire bonds. Each wire bond 24 connects one die pad 18 to one terminal lead 26. The connection instruction used to arrive at this assembly is net list 19 Table 1. This assembly FIG. 8 demonstrates why a die-down configured die can not be placed in a die-up package, the wire bonds cross each other and this is not a reliable technique and it is not used in practice. The crossing points will create conductive paths that will make the die inoperable. Hence, “POWER” shorts to “GROUND”, “CONTROL 1” shorts to “CONTROL 2”, and “DATA IN” shorts to “DATA OUT” in the example. This is why in the past, two different die designs have been needed for die-up and die-down.

FIG. 8D is an isometric view of FIG. 8A. The mold compound 38 has been removed from the FIG. to clearly view the package interior. The package assembly from FIG. 8C is overlaid into position to establish the proper net list connection from the PC board 42 to the package. This illustrates the crossing and shorting wires that result from using a die-down configured die in a die-up package.

U.S. Pat. No. 5,453,583, entitled “Interior Bond Pad Arrangements for Alleviating Thermal Stresses,” and No. 5,567,655, entitled “Method for Forming Interior Bond Pads Having Zigzag linear Arrangement,” both patents by Rostoker, et al and assigned to LSI Logic Corp., disclose inventions that arrange IC pads to reduce thermal stress. The pads are placed towards the interior of the die resulting in a zig-zag row of pads or even a compacted row of rectangular pads, where any wire bonds would have about the same lengths. Both of these patents discussed standard practices and techniques for handling and packaging a variety of IC's in a variety of mechanical packages. These patents and the references within these patents are incorporated herein by reference. These patents, however, do not suggest placing the pads of a single IC to accommodate die-up and die-down packages.

It would be advantageous, and it is an objective of this invention, to provide a single die that can be mounted in both the die-up and the die-down packages, without requiring additional transitional substrates or PC board to reverse the effective IC pad locations, while maintaining reliable wire bonding connections to the IC pads. There will be no criss-crossing the wire bonds between the IC pads and the package contacts.

### SUMMARY OF THE INVENTION

The above objective of the present invention is achieved in a method of making interconnections and an IC chip that provides a layout and ordering of the IC pads in a substantially linear format. The present inventive method, ordering and arrangement of IC pads provide a means of making wire bond connections between the IC pads and the contact terminals of the package that do not interfere or cross under or over each other when the same IC is mounted in a die-down or a die-up package.

It will be appreciated by those skilled in the art that although the following detailed description will proceed with reference being made to illustrative embodiments, the drawings, and methods of use, the present invention is not intended to be limited to these embodiments and methods of use. Rather, the present invention is of broad scope and is intended to be defined as only set forth in the accompanying claims.

### BRIEF DESCRIPTION OF THE DRAWINGS

FIGS. 1A, 1B, and 1C are block diagrams of the pad arrangements of prior art IC's;

FIGS. 2A, 2B, and 2C are block diagrams of the other pad arrangements of prior art IC's;

FIGS. 3A, 3B, 3C and 3D are illustrative end, bottom and isometric views of an IC of FIG. 1A mounted in a package and to a printed circuit board;

FIGS. 4A, 4B, 4C and 4D are illustrative end, bottom and isometric views of an IC of FIG. 2A mounted in a package and to a printed circuit board;

FIGS. 5A, 5B, 5C and 5D are other illustrative end, bottom and isometric views of an IC of FIG. 2A mounted in a package and to a printed circuit board;

FIGS. 6A, 6B, 6C and 6D are illustrative end, bottom and isometric views of an IC of FIG. 2A mounted in a package designed for the IC of FIG. 1A;

FIGS. 7A, 7B, 7C and 7D are illustrative end, bottom and isometric views of an IC of FIG. 1A mounted in a package designed for the IC of FIG. 2A;

FIGS. 8A, 8B, 8C and 8D are other illustrative end, bottom and isometric views of an IC of FIG. 1A mounted in a package designed for the IC of FIG. 2A;

FIG. 9A is a top view of the inventive in-line bond pads on the die;

FIG. 9B is a bottom view with the pads of FIG. 9A viewed from the back side;

FIG. 9C, is a table 3 of the net list of die with the bond pads of FIG. 9A;

FIG. 10A is a section end view showing a die-down chip assembled in a suitable package;

FIG. 10B is a bond pad side view of the in-line die with the die pad respective functions labeled to relate to the following FIG. 1C.

FIG. 10C is a package bottom view of the die of FIG. 10A;

FIG. 10D is an isometric view of the die of FIG. 10A;

FIG. 11A is a section end view showing a die up chip assembled in a suitable substrate package;

FIG. 11B is a bond pad side view of the in line die with the die pad respective functions labeled to relate to the following FIG. 11C;

FIG. 11C is the package top view of the die of FIG. 11A;

FIG. 11D is an isometric view of the die of FIG. 1A;

FIG. 12A is a section end view showing a die-up chip assembled in a suitable leadframe based package;

FIG. 12B is a bond pad side view of the in-line die with the die pad respective functions labeled to relate to the following FIG. 12C;

FIG. 12C is the package top view of the die of FIG. 12A;

FIG. 12D is an isometric view of the die of FIG. 12A;

FIGS. 13A, B, C and D are block diagrams of pad layouts and functions provided by the present invention;

FIGS. 14A and 14C are prior art pad layouts; and

FIGS. 14B, D, and E are pad layouts and functions provided by the present invention.

### DETAILED DESCRIPTION OF AN ILLUSTRATIVE EMBODIMENT

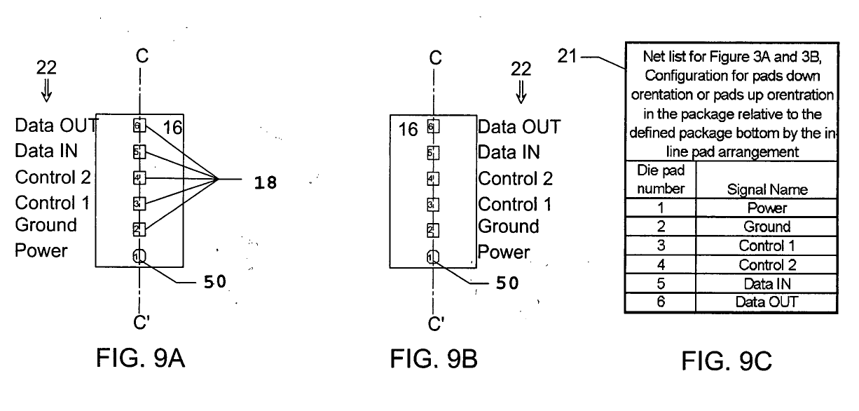

FIG. 9A illustrates a preferred embodiment of the present invention. A die 16 is formed with six bond pads centered vertically in a line down the body of the IC, not on the perimeter of the die as in prior art IC's. Each bond pad is numbered in a vertical in line manner with a first pad “pin 1” that has a unique geometry to make it optically distinguishable. The remaining pads are labeled, in this example, 2-6. The die in FIG. 9A has a net list 21, shown in FIG. 9C, and also referred to herein as “Table 3.” The net list 21 establishes the relationship between the geographic location of the die pads 18 and the electrical functions 22 of the die circuitry connected to those pads 18. The combination of each die pad 18 and each die function 22 makes a given die suitable for use in a variety of packages that may be large or small. The pad layout of the die 16 allows its use in pads up orientation and a pads down orientation, as described herein.

FIG. 9A is a view directly at the pads, while FIG. 9B is a view looking through the die 16. This establishes the direction of viewing a die from the back side because it is flipped over relative to the viewing direction of FIG. 9A. This flipping is as discussed above. In the die examples of this document the bond pad geographical position 1 stays at position one because it lays one the axis C-C′ that the die is flipped on. So to the remaining bond pad locations 2 through 6 remain in place and hence the inline bonding arrangement removes the crossing wires and poor bonding relationships illustrated above for prior art IC's.

Table 3, FIG. 9C, is the net list 21 for FIGS. 9A and 9B. This is a configuration of the electrical signals at each pad 18 for the in line configured die for use in the die-up or die-down packages.

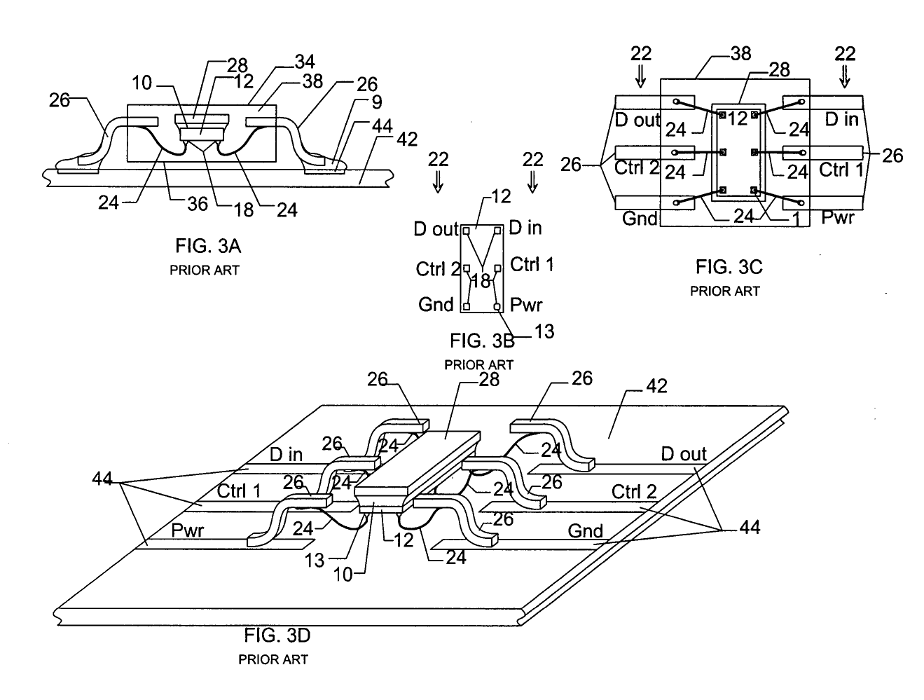

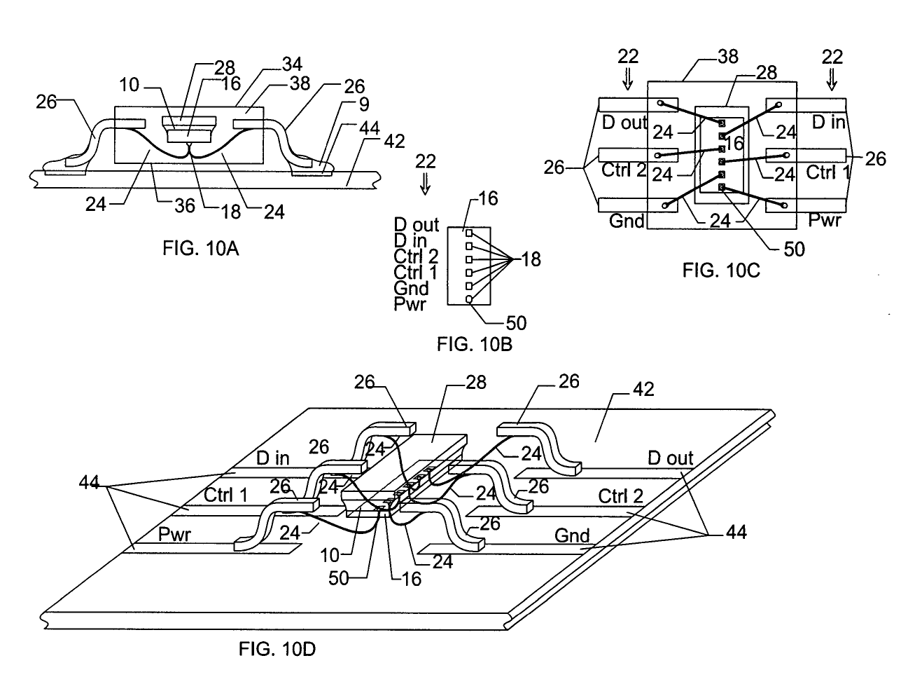

FIGS. 10A, B, C, and D are similar to FIGS. 3A, B, C, and D except with the inventive die 16 replacing the prior art die-down IC 12. As shown, the IC pads 18 are arranged in a line. Notice, in FIG. 10C there is no crossing of the wire bonds 24.

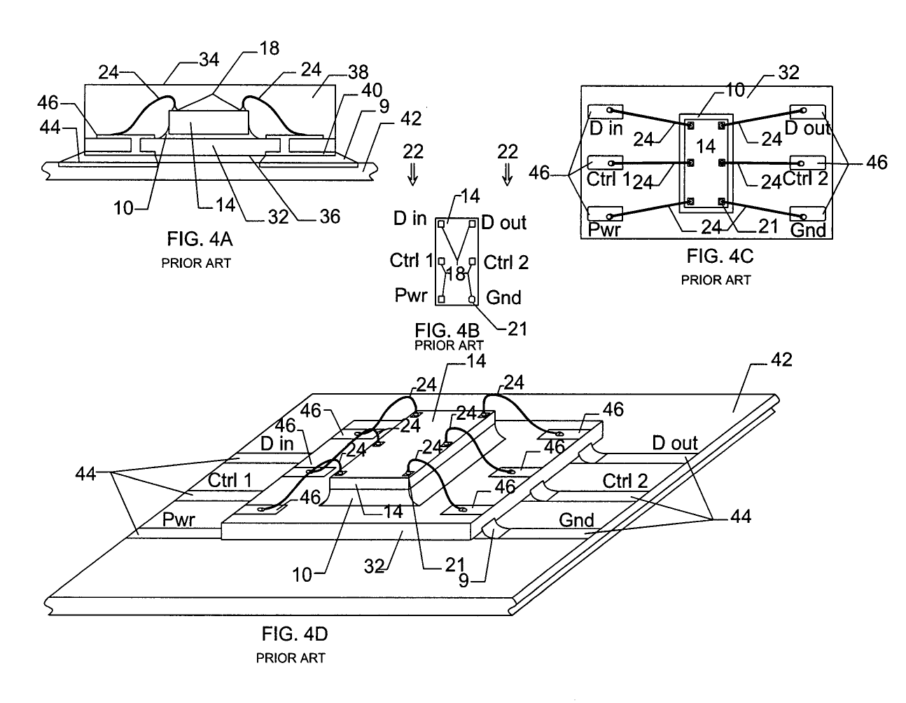

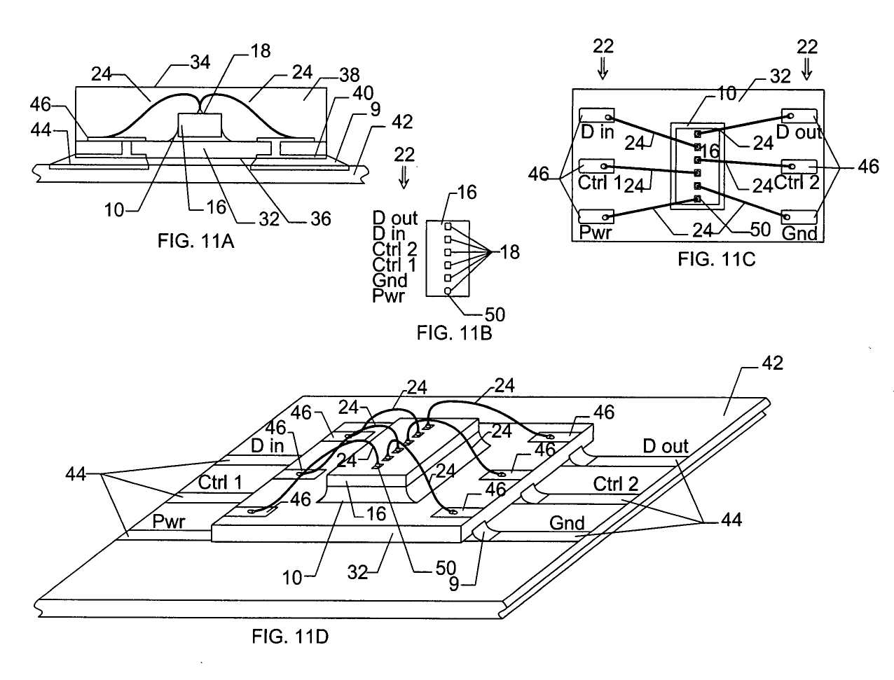

FIGS. 11A, B, C and D are similar to FIGS. 4A, B, C and D except with the inventive die 16 replacing the prior art die-up IC 14.

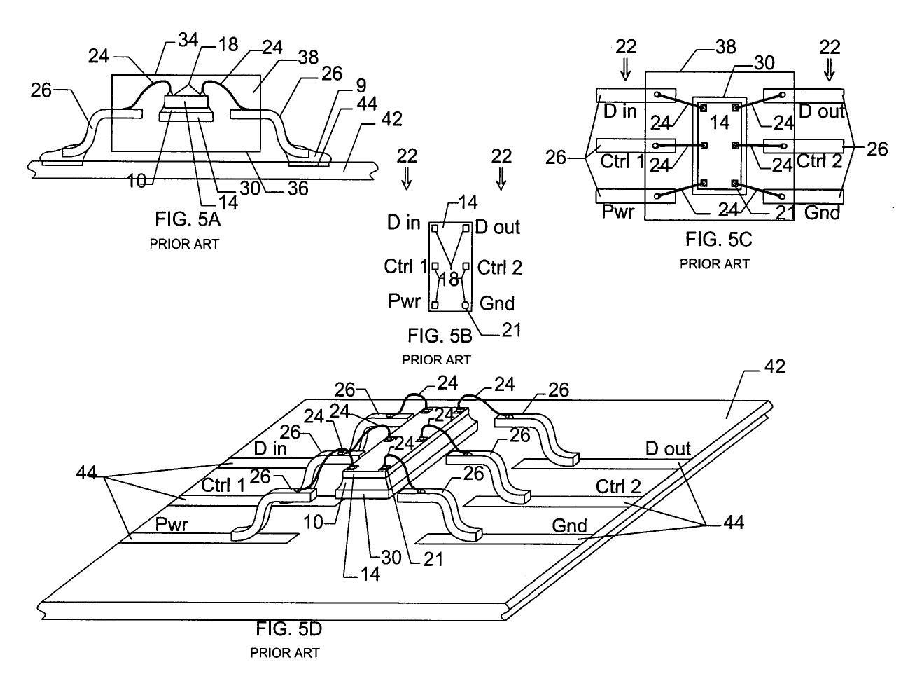

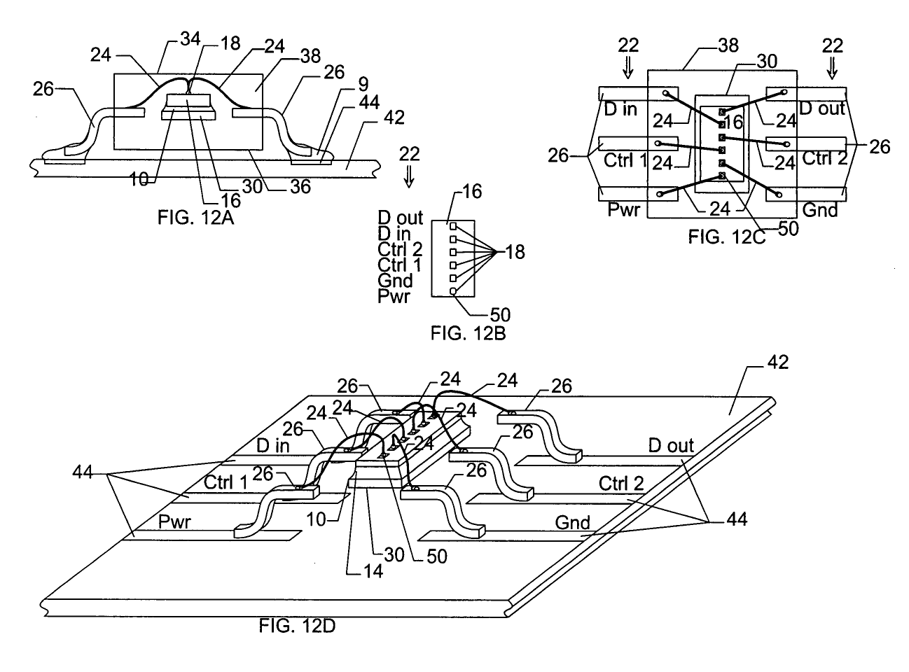

FIGS. 12A, B, C and D are similar to FIGS. 5A, B, C and D except with the inventive die 16 replacing the prior art die-up IC 14.

FIG. 10A shows an end view of an inline bond pad arranged die 16. This is an example of an embodiment of the inventive die 16 from FIGS. 3A and 3B with net list 21 in a die-down package. This end view of the inventive inline bond pad die 16 mounted in a package with the external plastic 38, viewed transparently here, showing the die 16 attached to a die attach paddle 28 of the leadframe. The IC 16 is attached by an adhesive material 10 to the bottom side of the die attach paddle 28 with each die pad 18 facing down toward the PC board 42. One wire bond 24 per die pad 18 is used to electrically connect to each terminal 26 that extend externally out of the package to make electrical contact by solder 9 with the copper land pattern 44 on the PC board 42. Surface 34 identifies what is referenced as the package top and surface 36 identifies what is referenced as the package bottom that faces the PC board 42.

FIG. 10B shows die inline configured die 16 with the signal names 22 and the first pad “pin 1” 50 to establish orientation of the in-line configured die 16 as it is mounted on the package die attach paddle 28.

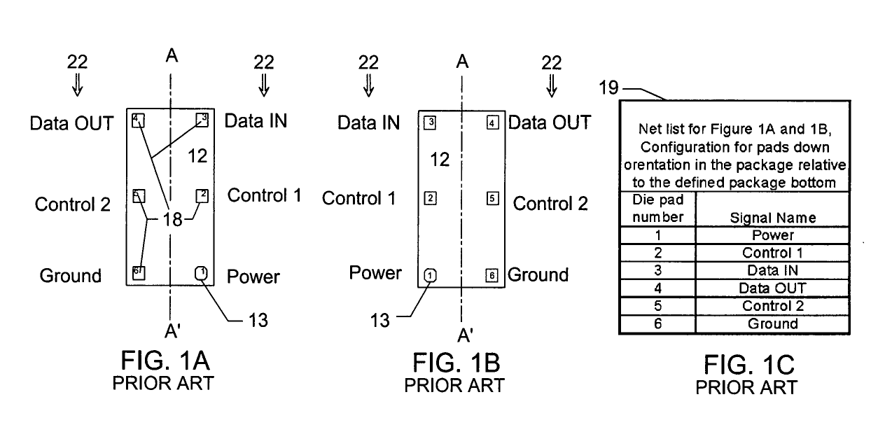

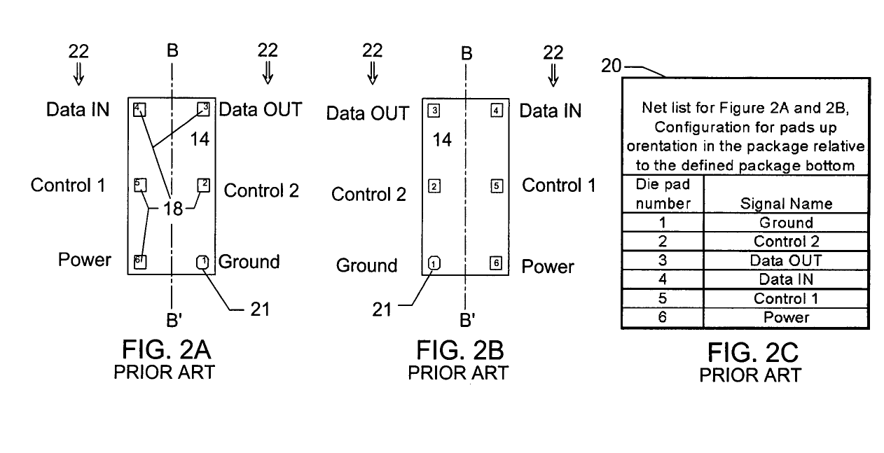

FIG. 1C shows a bottom up view of the package relative to the surface 36 in FIG. 10A with the die 16 from FIG. 10B overlaid into position without rotation onto the die attach paddle (DAP). The package plastic mold 38 is transparent to view the interior of the package. The electrical connectivity of the die 16 to the leads of the package 26 is done with wire bonds. Each wire bond 24 connects one die pad 18 to one lead 26. The connection instruction used to arrive at this assembly is net list 21 Table 3.

FIG. 10D is an isometric view of FIG. 10A. The mold compound 38 has been removed from the FIG. to clearly view the package interior. The package assembly from FIG. 10C is flipped over as described in FIG. 9B earlier in this document and then overlaid into position to establish the proper net list connection from the PCB 42 to the package FIG. 10C.

FIG. 11A shows an end view of an inline bond pad arranged die in a die-up substrate based package. This is an example of an embodiment of the inventive die 16 from FIGS. 9A and 9B with net list 21 in a die-up package. This end view of an inline bond pad die 16 mounted in a package with the external plastic 38, viewed transparently here, showing the die 16 attached to a substrate 32. The IC 16 is attached by an adhesive material 10 to the substrate 32 with each die pad 18 facing up and away from the PC board 42. One wire bond 24 connects each die pad 18 to one substrate terminal 46. Each substrate terminal 46 is connected from the top of the substrate 30 to the bottom external leads 40 to make electrical contact by solder 9 with the copper land pattern 44 on the PC board 42. Surface 34 identifies what is referenced as the package top and surface 36 identifies what is referenced as the package bottom that faces the PC board 42.

FIG. 11B shows die inline configured die 16 with the signal names 22 and the first pad “pin 1” 50 to establish orientation of the in-line configured die 16 as it is mounted on the package substrate 32.

FIG. 11C shows a top down view of the package relative to the surface 34 in FIG. 11A with the die 16 from FIG. 11B overlaid into position without rotation onto the DAP. The Package Plastic mold 38 is transparent to view the interior of the package. The electrical connectivity of the die 16 to the substrate terminals 46 is done with wire bonds. Each wire bond 24 connects one die pad 18 to one substrate terminal 46. The connection instruction used to arrive at this assembly is net list 21 Table 3.

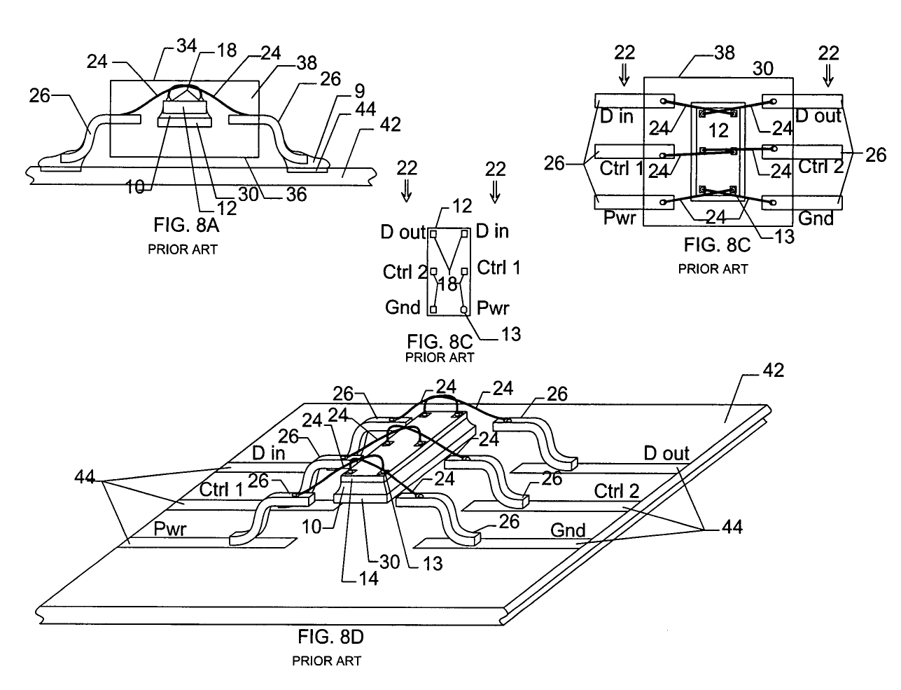

FIG. 11D is an isometric view of FIG. 11A. The mold compound 38 has been removed from the FIG. to clearly view the package interior. The package assembly from FIG. 11C is overlaid into position to establish the proper net list connection from the PC board 42 to the package shown in FIG. 8C.

FIG. 12A shows an end view of an inline bond pad arranged die 16. This is an example of an embodiment of the inventive die 16 shown in FIGS. 9A and 9B with net list 21 in a die-up package. This end view of an in-line bond pad die 16 mounted in a package with the external plastic 38, viewed transparently here, showing the die 16 attached to a die attach paddle 30 of the leadframe. The IC 16 is attached by an adhesive material 10 to the top side of the die attach paddle 30 with each die pad 18 facing up and away from the PC board 42. Each wire bond 24 connects one die pad 18 is used to electrically connect to each terminal 26 that extend externally out of the package to make electrical contact by solder 9 with the copper land pattern 44 on the PC board 42. Surface 34 identifies what is referenced as the package top and surface 36 identifies what is referenced as the package bottom that faces the PC board 42.

FIG. 12B shows die inline configured die 16 with the signal names 22 and the first pad “pin 1” 50 to establish orientation of the in-line configured die 16 as it is mounted on the package die attach paddle 30.

FIG. 12C shows a top down view of the package relative to the surface 36 in FIG. 12A with the die 16 from FIG. 12B overlaid into position without rotation. The package plastic mold 38 is transparent to view the interior of the package. The electrical connectivity of the die 16 to the leads of the package 26 is done with wire bonds. Each wire bond 24 connects one die pad 18 to one lead 26. The connection instruction used to arrive at this assembly is net list 21 Table 3.

FIG. 12D is an isometric view of FIG. 12A. The mold compound 38 has been removed from the FIG. to clearly view the package interior. The package assembly from FIG. 12C is overlaid into position to establish the proper net list connection from the PC board 42 to the package FIG. 9C.

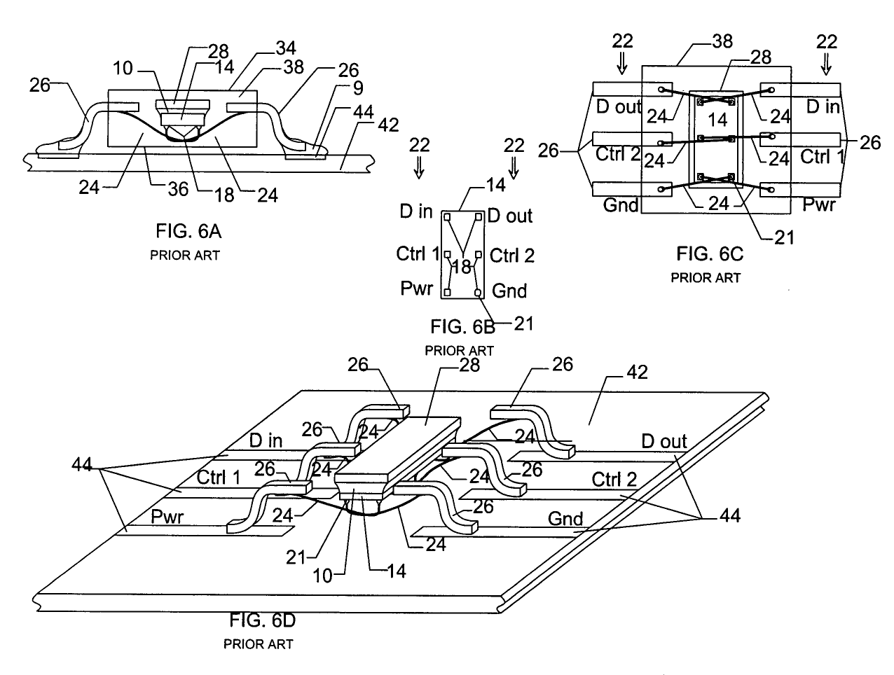

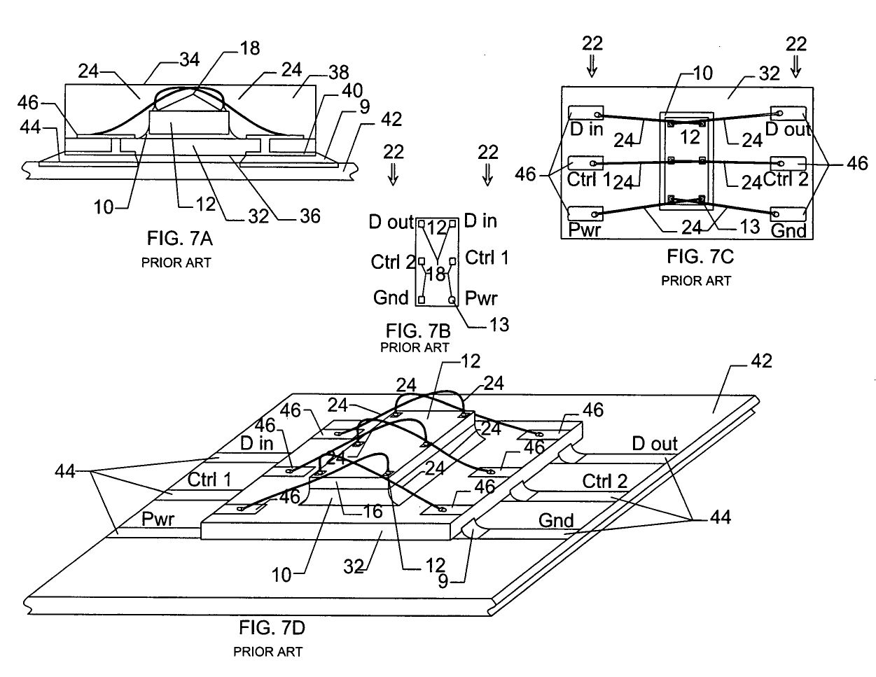

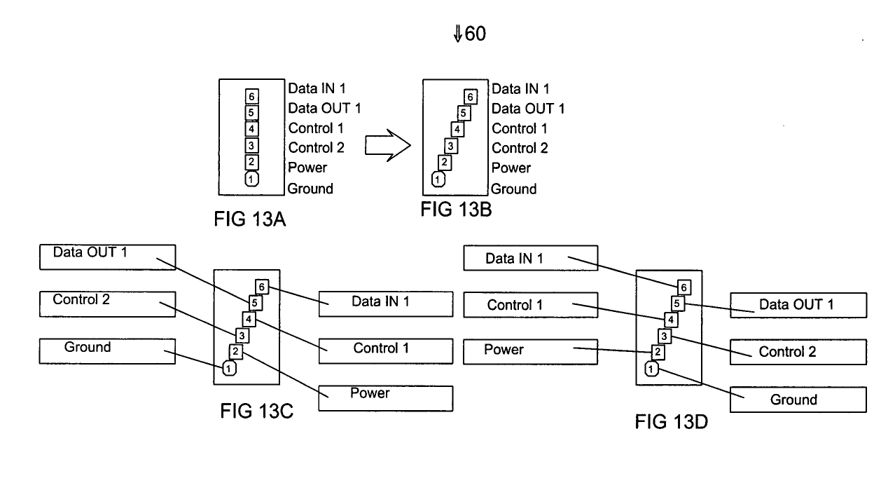

Notice that each wire bond 24 does not interfere or cross any other wire bond as in prior art of FIGS. 6, 7, and 8. Although, the line of IC pads is shown centered in the drawings of FIGS. 9B, 10b, 11b, and 12B, the line may be offset towards either edge of the IC. Moreover, as shown in FIG. 13B, the line of IC pads may be arranged in a diagonal 60 with respect to the edges of the IC and each IC pad may be offset from each other. This in-line diagonal arrangement would be advantageous in applications that require more extreme angles for connection of the wire bonds.

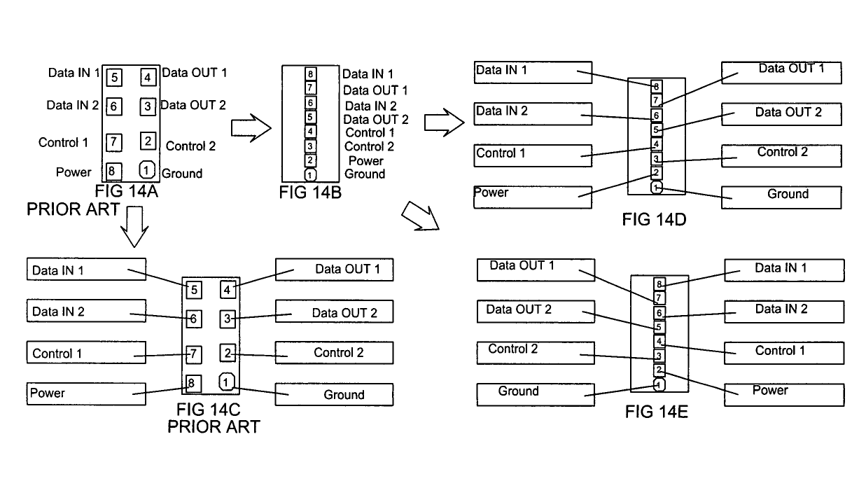

With respect to FIGS. 14A and 14B, notice that in prior art FIG. 14A the IC pads 18 have pad function names that can be reordered as in the inventive arrangement of FIG. 14B. The inventive arrangement of FIG. 14B provide the following the options shown in FIGS. 14D and 14E. FIG. 14D being a die-up bonding arrangement and FIG. 14E being a die-down bonding arrangement. Notice that the die 12 in FIG. 8A has no option and can only be used in a die-up package. Bonding arrangements of FIG. 14A and FIG. 14B are representative showing IC pads that are side by side in prior art FIG. 14A and realigned into a single line in FIG. 14B with the order of the side by side pads placed in alternating positions in the line. The geographic position numbering changes from periphery to inline and it is the functions that alternate into place.

The present invention provides an organization and method associated with reconfiguring and reordered IC pads that allows the same wire bonded chip to be used in a die-up and also in a die-down package. The specifics associated with making the IC itself, the package itself, the materials, bonding agents and techniques are well known in the art and have been so for many years. These skills, equipment, materials, techniques and processes for building IC packages with wire bonded IC's are well described in the above incorporated by reference U.S. patents, and many other references are available in application handbooks, etc. from most of the major IC producers, like Motorola, Fairchild, TI, LSI, VLSI, Analog Devices, etc. With that these details are not further described.

It should be understood that above-described embodiments are being presented herein as examples and that many variations and alternatives thereof are possible. Accordingly, the present invention should be viewed broadly as being defined only as set forth in the hereinafter appended claims.

1. A method for arranging the pads on an integrated circuit, the integrated circuit arranged to mount via wire bonds to contact terminals in an IC package constructed to make electrical connections to a printed circuit board, the method comprising the steps of:
aligning the integrated circuit pads into substantially a straight line; and
arranging the order of the integrated circuit pads within the substantially straight line, such that, when wire bonds are attached to the integrated circuit pads and to the corresponding package contacts terminal, the wire bonds do not run over or under any other wire bond.

2. The method of claim 1 wherein the substantially straight line is arranged in a diagonal with respect to the integrated circuit package.

3. The method of claim 1 wherein the substantially straight line is offset from a center line of the integrated circuit package.

4. The method of claim 1 wherein the integrated circuit pads are offset from each other in the substantially straight line.

5. An integrated circuit chip comprising:
pads on the integrated circuit for making electrical connections;
means for associating and ordering electrical functions to the pads;
wire bonds electrically connecting the pads to contacts on an integrated circuit package, the contacts constructed to bring the electrical connections outside the integrated circuit package;
means for aligning the pads into substantially a straight line; and
means for arranging the order of the integrated circuit pads within the substantially straight line, such that, the wire bonds do not run over or under any other wire bond.

6. The integrated circuit chip of claim 5 wherein the substantially straight line is arranged in a diagonal with respect to the integrated circuit package.

7. The integrated circuit chip of claim 5 wherein the substantially straight line is offset from a center line of the integrated circuit.

8. The integrated circuit chip of claim 5 wherein the integrated circuit pads are offset from each other in the substantially straight line.

9. A method for arranging the pads on an integrated circuit within the substantially straight line, such that the resulting geography of die bond pads allows for the use of that die in both a die-up IC package and die-down IC package with the resulting wire bonds of both assemblies existing absent of crossing or touching wire bonds.

10. The method of claim 9 wherein the substantially straight line is arranged in a diagonal with respect to the integrated circuit package.

11. The method of claim 9 wherein the substantially straight line is offset from a center line of the integrated circuit.

12. The method of claim 9 wherein the integrated circuit pads are offset from each other in the substantially straight line.

13. The method of claim 9 wherein the non crossing or touching wire bonds are the same or different assigned electrical functions.
